(19) United States
(12) Patent Application Publication
(10) Pub. No.: US 2024/0378712 A1
(43) Pub. Date: Nov. 14, 2024

(54) DEVICE AND METHOD FOR ANALYZING DEFECT IN ULTRASONIC TESTING USING THREE-DIMENSIONAL DEEP LEARNING MODEL

(71) Applicant: DOOSAN ENERBILITY CO, LTD., Changwon (KR)

(72) Inventors: June Sung SEO, Gimpo (KR); Jung Min LEE, Seoul (KR)

(21) Appl. No.: 18/610,339

(22) Filed: Mar. 20, 2024

(30) Foreign Application Priority Data
May 11, 2023 (KR) 10-2023-0061162

(51) Int. Cl. G06T 7/00; G06T 3/4046; G06T 9/00; G06V 10/82

(52) U.S. Cl. CPC G06T 7/0002; G06T 9/00; G06V 10/82; G06T 3/4046; G06T 2200/04; G06T 2207/20081; G06T 2207/20084

(57) ABSTRACT

A device and method for analyzing a defect in ultrasonic testing using a three-dimensional deep learning model is proposed. The method includes preparing three-dimensional raw data by collecting a plurality of two-dimensional inspection images obtained by ultrasonic testing of an inspection object and stacking the plurality of two-dimensional inspection images; generating input data for a deep learning model by processing the three-dimensional raw data; deriving representation data, which is an inferenced three-dimensional image representing the defect of the inspection object, through a first feature transformation by applying first weights in a trained state to the input data within a generation network of the deep learning model; and determining a defect type of the inspection object by inputting the representation data to a detecting network of the deep learning model.

### CROSS REFERENCE TO RELATED APPLICATION

The present application claims priority to Korean Patent Application No. 10-2023-0061162, filed May 11, 2023, the entire contents of which are incorporated herein for all purposes by this reference.

### BACKGROUND OF THE INVENTION

### Field of the Invention

The present disclosure relates to defect analysis technology and, more particularly, to a device and method for analyzing a defect in ultrasonic testing (UT) using a three-dimensional deep learning model.

### Description of the Related Art

Conventionally, a person in charge of inspection determines presence or absence of a defect while visually inspecting raw data, a top view, and a section view of an object on the basis of signals extracted through ultrasonic testing, or analyzes the defect by using one-dimensional signal data or two-dimensional image data. However, although the one-dimensional signal data allows checking a position of the defect with coordinate values, checking a shape of the defect is difficult, and although the two-dimensional image data allows checking the shape of the defect, checking a depth of the defect is not possible.

### SUMMARY OF THE INVENTION

An objective of the present disclosure is to provide a device and method for analyzing a defect in ultrasonic testing using a three-dimensional deep learning model in order to solve the above problems.

According to a preferred exemplary embodiment of the present disclosure to achieve the above-described objective, there is provided a method for analyzing a defect, the method including: preparing, by a collection unit, three-dimensional raw data by collecting a plurality of two-dimensional inspection images obtained by ultrasonic testing of an inspection object and stacking the plurality of collected two-dimensional images; generating, by an augmentation unit, input data for a deep learning model by processing the raw data; and deriving, by an analysis unit, representation data which is a three-dimensional image representing the defect of the inspection object by performing weighting operations in which weights with completed learning on the input data are applied through a generation network of the deep learning model.

The method may further include: deriving, by the analysis unit, detection data for predicting a type of defect of the inspection object as a probability by performing weighting operations in which weights with completed learning on the representation data are applied through a detecting network of the deep learning model; and detecting, by the analysis unit, the type of defect in the inspection object according to the probability.

The deriving of the representation data may include: deriving, by a plurality of encoding modules of the generation network, a latent vector represented as a feature map by compressing the input data sequentially; and deriving, by a latent module and a plurality of decoding modules of the generation network, the representation data by sequentially expanding the latent vector and restoring the latent vector to fit sizes of the input data.

The deriving of the latent vector may include: performing, by each of one or more convolution layers of each encoding module, a convolution operation, a batch normalization operation, and an operation using an activation function (e.g., ReLU) on the input data or a feature map to generate a feature map; and downsampling, by a pooling layer of each encoding module, the feature map through a pooling operation.

The deriving of the representation data may include: performing, by each of one or more convolution layers of the latent module, a convolution operation, a batch normalization operation, and an operation using an activation function on a feature map to generate a feature map; and upsampling, by an up-convolution layer of the latent module, the feature map through an up-convolution operation.

The deriving of the representation data may include: combining, by a concatenate layer of each decoding module, a feature map input from a corresponding encoding module and a feature map input from the latent module or a previous decoding module; performing, by each of one or more convolution layers of each decoding module, a convolution operation, a batch normalization operation, and an operation using an activation function on a feature map; and upsampling, by an up-convolution layer of each decoding module, a feature map through an up-convolution operation.

In the generating of the input data, the augmentation unit may perform data augmentation by dividing each two-dimensional inspection image into a plurality of pixel patches according to the number of pooling operations of the generation network.

In the generating of the input data, the augmentation unit may divide each two-dimensional inspection image into 2ⁿ or more pixel patches, and n may be the number of pooling operations of the generation network.

The method may further include: preparing, by the learning unit before the preparing of the raw data, a plurality of pieces of first training data comprising the input data generated through data augmentation and target data which is a three-dimensional image representing the defect of the inspection object from the three-dimensional raw data in which the plurality of two-dimensional inspection images obtained by the ultrasonic testing for the inspection object having the defect is stacked; inputting, by the learning unit, the input data into the generation network; generating, by the generation network, the representation data through weighting operations in which weights with incompleted learning on the input data are applied; deriving, by the learning unit, a generation loss representing a difference between the representation data and the target data through a loss function; and performing, by the learning unit, optimization for modifying the weights of the generation network so as to maximally reduce the generation loss.

In the deriving of the generation loss, the learning unit may derive the loss according to Equations below:

$${L}_{g} = 1 - {P ( o , t )}_{ijk}$$

$${P ( o , t )}_{ijk} = {\sum }_{i} {\sum }_{j} {\sum }_{k} \frac{( 2 {μ}_{o} {μ}_{t} + {C}_{1} ) ( 2 {σ}_{o} {σ}_{t} + {C}_{2} )}{( {μ}_{o}^{2} + {μ}_{t}^{2} + {C}_{1} ) ( {σ}_{o}^{2} + {σ}_{t}^{2} + {C}_{2} )}$$

where Lg is the generation loss, o is the representation data, t is the target data, P(o, t) is similarity between the representation data and the target data, i, j, and k are indices for identifying coordinates of three-dimensional pixel patches of the representation data and target data, μ is luminance of a corresponding pixel patch of the representation data and target data, and σ is contrast of the corresponding pixel patch of the representation data and target data.

The method may further include: preparing, by the learning unit, a plurality of pieces of second training data comprising the input data and a label indicating the type of defect of the inspection object; inputting, by the learning unit, the input data into the generation network; generating, by the generation network, the representation data through the weighting operations in which the weights with the completed learning on the input data are applied; generating, by the detecting network, detection data for predicting the type of defect as a probability through weighting operations in which weights with incompleted learning on the representation data are applied; deriving, by the learning unit, a prediction loss representing a difference between the detection data and the label through a loss function; and performing, by the learning unit, optimization for modifying the weights of the detecting network in a state of fixing the weights of the generation network so as to maximally reduce the prediction loss.

According to the preferred exemplary embodiment of the present disclosure to achieve the above-described objective, there is provided a device for analyzing a defect, the device including: a collection unit configured to prepare three-dimensional raw data by collecting a plurality of two-dimensional inspection images obtained by ultrasonic testing of an inspection object and stacking the plurality of collected two-dimensional images; an augmentation unit configured to generate input data for a deep learning model by processing the raw data; and an analysis unit configured to derive representation data which is a three-dimensional image representing the defect of the inspection object by performing weighting operations in which weights with completed learning on the input data are applied through a generation network of the deep learning model.

The analysis unit may derive detection data for predicting a type of defect of the inspection object as a probability by performing weighting operations in which weights with completed learning on the representation data are applied through a detecting network of the deep learning model and detects the type of defect in the inspection object according to the probability.

The generation network may include: a plurality of encoding modules configured to derive a latent vector represented as a feature map by compressing the input data sequentially; and a latent module and a plurality of decoding modules, which are configured to derive representation data by sequentially expanding the latent vector and restoring the latent vector to fit sizes of the input data.

Each encoding module may include: each of one or more convolution layers of each encoding module configured to perform a convolution operation, a batch normalization operation, and an operation using an activation function on the input data or a feature map to generate a feature map; and a pooling layer configured to downsample the feature map through a pooling operation.

The latent module may include: each of one or more convolution layers configured to perform a convolution operation, a batch normalization operation, and an operation using an activation function on a feature map to generate a feature map; and an up-convolution layer configured to upsample the feature map through an up-convolution operation.

Each decoding module may include: a concatenate layer configured to combine a feature map input from a corresponding encoding module and a feature map input from the latent module or a previous decoding module; each of one or more convolution layers configured to perform a convolution operation, a batch normalization operation, and an operation using an activation function on an input feature map; and an up-convolution layer configured to upsample a feature map through an up-convolution operation.

An augmentation unit may perform data augmentation by dividing each two-dimensional inspection image into a plurality of pixel patches according to the number of pooling operations of the generation network.

The augmentation unit may divide each two-dimensional inspection image into 2ⁿ or more pixel patches, and n may be the number of pooling operations of the generation network.

The device may further include a learning unit configured to prepare, before the preparing of the raw data, a plurality of pieces of first training data comprising the input data generated through the data augmentation and target data which is a three-dimensional image representing the defect of the inspection object from the three-dimensional raw data in which the plurality of two-dimensional inspection images obtained by the ultrasonic testing for the inspection object having the defect is stacked, input the input data into the generation network, cause the generation network to generate the representation data through weighting operations in which weights with incompleted learning on the input data are applied, derive a generation loss representing a difference between the representation data and the target data through a loss function, and perform optimization for modifying the weights of the generation network so as to maximally reduce the generation loss.

The learning unit may derive the loss according to Equations below:

$${L}_{g} = 1 - {P ( o , t )}_{ijk}$$

$${P ( o , t )}_{ijk} = {\sum }_{i} {\sum }_{j} {\sum }_{k} \frac{( 2 {μ}_{o} {μ}_{t} + {C}_{1} ) ( 2 {σ}_{o} {σ}_{t} + {C}_{2} )}{( {μ}_{o}^{2} + {μ}_{t}^{2} + {C}_{1} ) ( {σ}_{o}^{2} + {σ}_{t}^{2} + {C}_{2} )}$$

where Lg is the generation loss, o is the representation data, t is the target data, P(o, t) is similarity between the representation data and the target data, i, j, and k are indices for identifying coordinates of three-dimensional pixel patches of the representation data and target data, μ is luminance of a corresponding pixel patch of the representation data and target data, and σ is contrast of the corresponding pixel patch of the representation data and target data.

The learning unit may prepare a plurality of pieces of second training data comprising the input data and a label indicating the type of defect of the inspection object, input the input data into the generation network, cause the generation network to generate the representation data through the weighting operations in which the weights with the completed learning on the input data are applied, cause the detecting network to generate detection data for predicting the type of defect as a probability through weighting operations in which weights with incompleted learning on the representation data are applied, derive a prediction loss representing a difference between the detection data and the label through a loss function, and perform optimization for modifying the weights of the detecting network in a state of fixing the weights of the generation network so as to maximally reduce the prediction loss.

According to the present disclosure, three-dimensional defects (i.e., three-dimension objects) which are difficult to be predicted at once may be detected by using a one-dimensional or two-dimensional model through a three-dimensional deep learning model. Three-dimensional input data is used to perform analysis, so that shapes similar to the shapes of actual defects may be analyzed. That is, in the present disclosure, the types of the three-dimensional defects (of the three-dimensional objects) difficult to be predicted and confirmed simultaneously may be predicted and confirmed at once by using one-dimensional or two-dimensional modeling. Moreover, in the present disclosure, the analysis is performed by dividing raw data into a form of pixel patches of a predetermined ratio or more, whereby a GPU may be used efficiently despite the lack of actual defect data, and small-sized defects may be recognized from large-volume image data as well.

### BRIEF DESCRIPTION OF THE DRAWINGS

FIG. 1 is a view illustrating a configuration of a device for analyzing a defect in ultrasonic testing using a three-dimensional deep learning model according to an exemplary embodiment of the present disclosure.

FIG. 2 is a view illustrating raw data generated by the ultrasonic testing according to the exemplary embodiment of the present disclosure.

FIG. 3 is a view illustrating input data for the three-dimensional deep learning model according to the exemplary embodiment of the present disclosure.

FIG. 4 is a view illustrating a configuration of the deep learning model for analyzing the defect in the ultrasonic testing according to the exemplary embodiment of the present disclosure.

FIGS. 5 and 6 are flowcharts illustrating a learning method of the deep learning model for analyzing the defect in the ultrasonic testing using the 3D deep learning model according to the exemplary embodiment of the present disclosure.

FIG. 7 is a flowchart illustrating a method for analyzing the defect in the ultrasonic testing using the three-dimensional deep learning model according to the exemplary embodiment of the present disclosure.

FIG. 8 is a view illustrating a computing device according to the exemplary embodiment of the present disclosure.

### DETAILED DESCRIPTION OF THE INVENTION

The present disclosure may be modified in various ways and may have various exemplary embodiments, and thus a specific exemplary embodiment will be exemplified and described in detail in the specific descriptions. However, this is not intended to limit the present disclosure to a particular disclosed form. On the contrary, the present disclosure is to be understood to include all various alternatives, equivalents, and substitutes that may be included within the idea and technical scope of the present disclosure.

The terminology used in the present disclosure is for the purpose of describing a particular exemplary embodiment only, and is not intended to be limiting. As used herein, the singular forms are intended to include the plural forms as well, unless the context clearly indicates otherwise. In addition, it will be further understood that the terms “comprise”, “include”, “have”, etc. when used in the present disclosure, specify the presence of stated features, integers, steps, operations, elements, components, and/or combinations thereof, but do not preclude the possibility of the presence or addition of one or more other features, integers, steps, operations, elements, components, and/or combinations thereof.

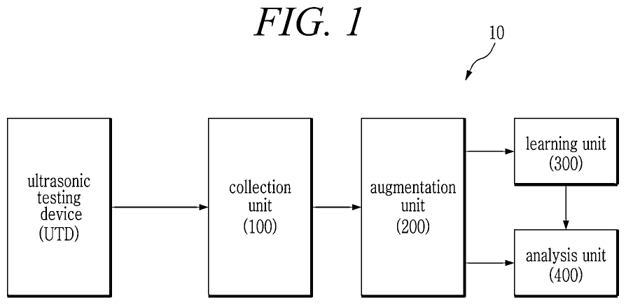

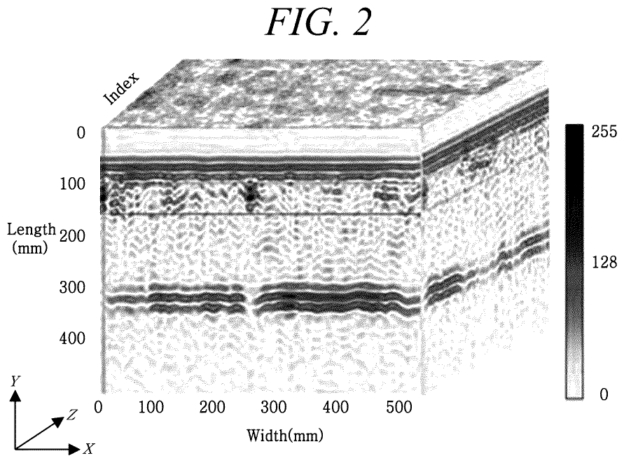

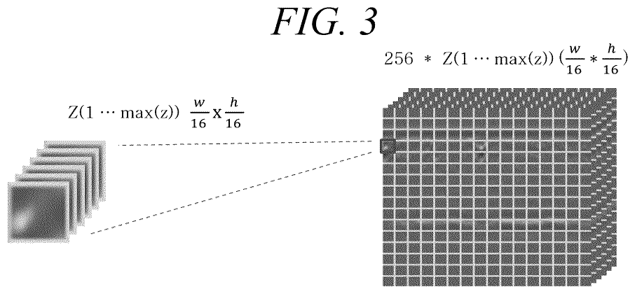

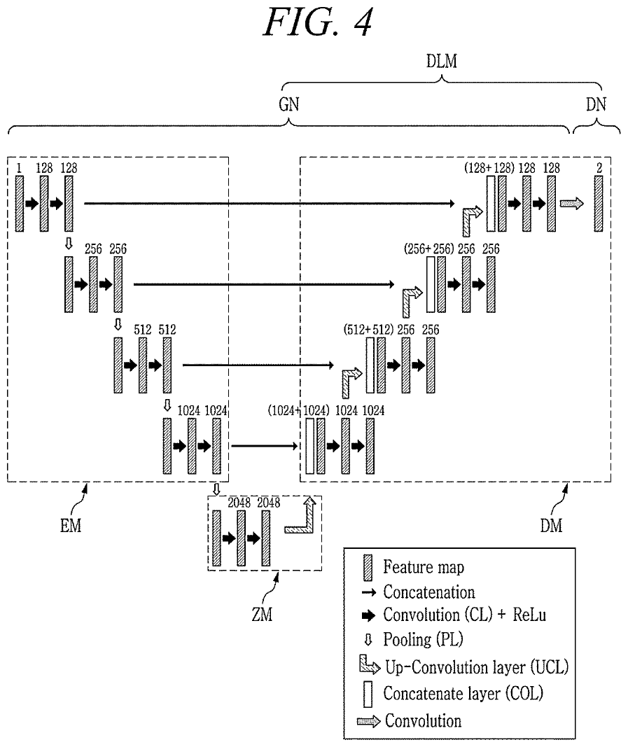

First, a device for analyzing a defect in ultrasonic testing using a three-dimensional deep learning model according to an exemplary embodiment of the present disclosure will be described. FIG. 1 is a view illustrating a configuration of the device for analyzing the defect in the ultrasonic testing using the three-dimensional deep learning model according to the exemplary embodiment of the present disclosure. FIG. 2 is a view illustrating raw data generated by the ultrasonic testing according to the exemplary embodiment of the present disclosure. FIG. 3 is a view illustrating input data for the three-dimensional deep learning model according to the exemplary embodiment of the present disclosure. FIG. 4 is a view illustrating a configuration of the deep learning model for analyzing the defect in the ultrasonic testing according to the exemplary embodiment of the present disclosure.

Referring to FIG. 1, the device 10 (hereinafter referred to as “an analysis device”) for analyzing the defect in the ultrasonic testing using the three-dimensional deep learning model according to the exemplary embodiment of the present disclosure includes a collection unit 100, an augmentation unit 200, a learning unit 300, and an analysis unit 400.

The collection unit 100 is for generating three-dimensional raw data by collecting a plurality of two-dimensional inspection images obtained by ultrasonic testing (UT) on an inspection object from an ultrasonic testing device (UTD) and stacking the plurality of collected two-dimensional images. The ultrasonic testing device (UTD) is a device for performing the ultrasonic testing (UT), and may emit ultrasonic waves to the inspection object and generate the inspection images through reflection signals reflected from the inspection object in response to the emitted ultrasonic waves. In this way, the two-dimensional inspection images are prepared by the ultrasonic testing. That is, each inspection image is generated by scanning the inspection object by the ultrasonic testing device (UTD). The collection unit 100 may receive each two-dimensional inspection image from the ultrasonic testing device (UTD). Each of such two-dimensional inspection images generated is composed to have scan axes of B(X, Y), D(Z, Y), and C(X, Z). Accordingly, the collection unit 100 may collect the plurality of two-dimensional inspection images, and as shown in FIG. 2, may align and stack the plurality of two-dimensional inspection images along each axis (X, Y, Z), thereby generating three-dimensional raw data represented in a three-dimensional form of X, Y, and Z. Here, X may be width, Y may be length, and Z may be index.

The augmentation unit 200 is for generating input data for a deep learning model DLM by processing the raw data generated by the collection unit 100. The deep learning model DLM includes a generation network GN and a detecting network DN.

Referring to FIGS. 3 and 4, the generation network GN includes a plurality of pooling layers PL, and through a pooling operation (i.e., a Max pooling), each pooling layer PL downsamples the input data or feature map which is input from a previous layer through the pooling operation. Accordingly, in order to preserve features of the input data, the augmentation unit 200 performs data augmentation by dividing each two-dimensional inspection image of the raw data into a plurality of pixel patches in accordance with the number of the pooling operations in the generation network GN, thereby generating the input data. More specifically, when generating the input data through the data augmentation, the augmentation unit 200 divides the two-dimensional inspection images of the raw data into at least 2ⁿ pixel patches. The augmentation unit 200 preferably divides the two-dimensional inspection images of the raw data into 2ⁿ⁺¹ pixel patches. Here, n indicates the number of pooling layers or the pooling operations of the generation network GN.

The learning unit 300 is for allowing the deep learning model DIM to learn according to the exemplary embodiment of the present disclosure. The deep learning model DLM includes the generation network GN and the detecting network DN. The deep learning model DLM with completed learning is provided to the analysis unit 400. A learning method of the deep learning model DLM will be described in more detail below.

By using the deep learning model DLM, the analysis unit 400 may detect an image representing a type of defect of an inspection object, that is, a type of defect of representation data and an inspection object. The analysis unit 400 derives the representation data by performing weighting operations or feature transformations in which fully trained weights are applied to the input data through the generation network GN of the deep learning model DLM. Here, the representation data is an inferenced three-dimensional image representing the defect of the inspection object. In addition, the analysis unit 400 derives detection data by performing weighting operations or feature transformations in which fully trained weights are applied to the representation data through the detecting network DN of the deep learning model DLM. The detection data represents the type of defect in the inspection object as a probability. In addition, the analysis unit 400 may detect the type of defect in the inspection object according to a probability for each type of defect of the inspection object in the detection data.

Referring to FIG. 4, the deep learning model DLM according to the exemplary embodiment of the present disclosure includes the generation network GN and the detecting network DN. The deep learning model DLM including the generation network GN and the detecting network DN includes a plurality of layers, and the plurality of layers includes a plurality of operations. In addition, the plurality of layers is connected to each other by using weights. Operation results of any one layer are applied with weights and input to the next layer. That is, any one layer of the deep learning model DLM receives input of values applied with the weights from the previous layer, performs operations on the values, and transmits operation results as input to the next layer. The plurality of layers may be composed of a convolution layer, a pooling layer, an up-convolution layer, a concatenate layer, a fully-connected layer, etc. Each of the layers takes an input and produces an output. The input of a convolution later may be raw input data or a feature map processed from a preceding convolution layer which is referred to as an input feature map. The output of a convolution later may be referred to as a convolved feature map.

Examples of such operations may include a convolution operation, a pooling operation, an up-convolution operation, an operation using an activation function, etc. Operations of the deep learning model DLM including the generation network GN and the detecting network DN will be referred to as “feature transformations” or “weighting operations”.

When input data is input, the generation network GN generates representation data by performing weighting operations on the input data. The representation data is an inferenced three-dimensional image representing a defect of an inspection object, and is represented as feature maps. The representation data is input to the detecting network DN, and when the representation data is input, the detecting network DN performs weighting operations on the representation data to derive detection data. The detection data is data for predicting a type of defect in the inspection object as a probability. Here, the type of defect in the inspection object may include, for example, a wrinkle, delamination, a dry area, etc.

A generation network GN may be exemplified as a 3D U-Net. The generation network GN includes a plurality of encoding modules EM, a latent module ZM, and a plurality of decoding modules DM. In a case of the exemplary embodiment in FIG. 4, four encoding modules EM, one latent module ZM, and four decoding modules DM are sequentially illustrated.

The plurality of encoding modules EM is for deriving a latent vector by compressing features of input data. The latent module ZM and the plurality of decoding modules DM are for deriving representation data by restoring the latent vector according to sizes of the input data. The features and latent vector are represented in a form of feature map.

Accordingly, each of the plurality of encoding modules EM generates a feature map by compressing input data or a feature map which is input. Accordingly, the plurality of encoding modules EM may sequentially compress the input data, and derive a latent vector represented as a feature map.

In addition, each of the latent module ZM and plurality of decoding modules DM generates a feature map by expanding an input feature map. Accordingly, the latent module ZM and the plurality of decoding modules DM may derive representation data by expanding the latent vector represented as the feature map.

Each of the plurality of encoding modules EM includes one or more convolution layers CL each performing a convolution operation, batch normalization, and an operation using an activation function on input, i.e., the input data or a feature map received from a preceding layer. Examples of the activation function include a sigmoid, a hyperbolic tangent (tanh), an exponential linear unit (ELU), a rectified linear unit (ReLU), a leaky ReLU, Maxout, Minout, Softmax, etc., and it is preferable to use the rectified linear unit (ReLU).

The feature map output from the last convolution layer CL of each of the plurality of encoding modules EM is input to a corresponding decoding module DM. Each of the plurality of encoding modules EM further includes a pooling layer PL that performs a pooling operation (i.e., a Max pooling) on a feature map. The pooling layer PL downsamples the input feature map through the pooling operation (i.e., the Max pooling). The feature map output from the pooling layer PL of each of the plurality of encoding modules EM is input to the next encoding module EM.

The latent module ZM includes one or more convolution layers CL each performing a convolution operation, batch normalization, and an operation using an activation function (e.g., a ReLU) on a feature map. The latent module ZM further includes an up-convolution layer UCL that performs an up-convolution operation on a feature map. The up-convolution layer UCL upsamples the input feature map through the up-convolution operation. The feature map output from the up-convolution layer UCL of the latent module ZM is input to the first decoding module DM.

Each of the plurality of decoding modules DM includes a concatenate layer COL that concatenates a feature map input from a corresponding encoding module EM and a feature map input from the latent module ZM or a previous decoding module DM. Any one decoding module DM may correspond to an encoding module EM that outputs a feature map having the same standard as that of input, and may receive the feature map from the encoding module EM corresponding in this way. In addition, when a feature map is input to any one decoding module DM from a previous decoding module DM, a concatenate layer of the corresponding decoding module DM performs a concatenate operation that concatenates the feature map input from the previous decoding module DM and a feature map input from a corresponding encoding module EM.

Each of the plurality of decoding modules DM further includes one or more convolution layer CL each performing a convolution operation, batch normalization, and an operation using an activation function (e.g., a ReLU) on an input feature map. Each of the plurality of decoding modules DM further includes an up-convolution layer UCL that performs an up-convolution operation on a feature map. The up-convolution layer UCL upsamples the input feature map through the up-convolution operation. A feature map output from the up-convolution layer UCL of the decoding module DM is input to a next decoding module DM. In particular, a feature map output by the last decoding module DM may be representation data of the present disclosure. The representation data is a three-dimensional (3D) image representing a defect of an inspection object.

A detecting network DN may be exemplified as a convolutional neural network (CNN). However, the detecting network DN is not limited thereto, and any type of artificial neural network with an output for classification of a defect in an inspection object may be the detecting network DN of the present disclosure. The detecting network DN includes at least one or more convolutional layers CL and at least one or more fully-connected layers.

In the included convolution layer CL, each of the one or more convolution layers CL performs a convolution operation and an operation using an activation function. A batch normalization operation may be performed prior to the operation using the activation function.

Each convolution layer CL outputs a feature map by performing a feature transformation or a weighting operation, i.e., a convolution operation, and an operation using an activation function on the representation data.

Each fully-connected layer derives detection data by performing a feature transformation or a weighting operation, i.e., an operation using an activation function, on a feature map. In other words, a fully-connected layer may become an output layer. The detection data is data for predicting a type of defect in an inspection object as a probability. For example, it is assumed that the type of defect in the inspection object includes a wrinkle and delamination. Then, the detection data represents both a probability that the type of defect in the inspection object is the wrinkle and a probability that the type of defect in the inspection object is the delamination. For example, the learned defects are assumed to be the wrinkle and delamination. In this case, an output of the detecting network DN may be output as “[wrinkle, delamination]=[0.749, 0.251]”. This means that there is a 75% probability that the defect in the inspection object is the wrinkle and a 25% probability that the defect in the inspection object is the delamination. Accordingly, the analysis unit 400 may determine that the type of defect in the inspection object is the wrinkle.

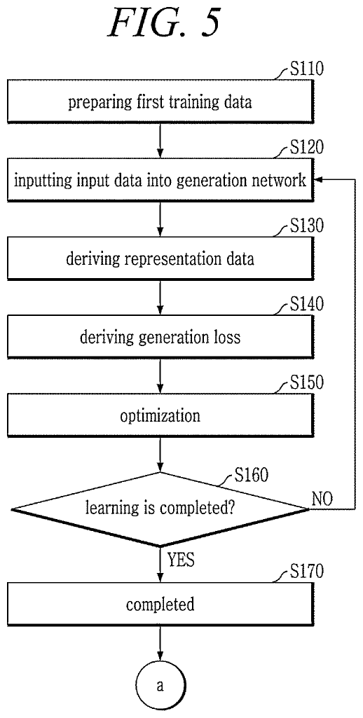

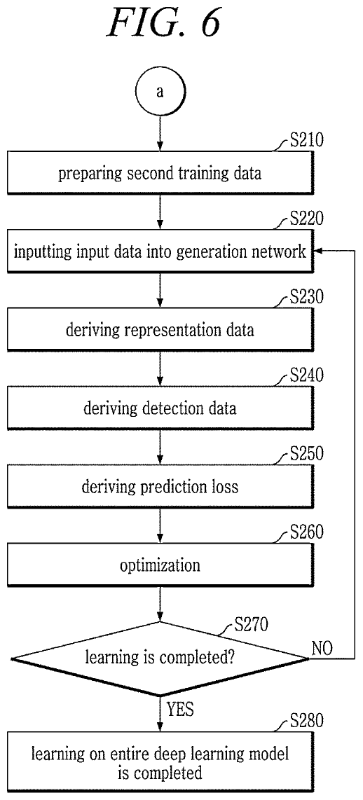

Next, a learning method of a deep learning model for analyzing a defect in ultrasonic testing using a 3D deep learning model according to the exemplary embodiment of the present disclosure will be described. FIGS. 5 and 6 are flowcharts illustrating the learning method of the deep learning model for analyzing the defect in the ultrasonic testing using the 3D deep learning model according to the exemplary embodiment of the present disclosure.

Referring to FIG. 5, in step S110, a learning unit 300 prepares a plurality of first training data. The training data includes training input data and target data. The training input data is prepared in a way of collecting a plurality of historical two-dimensional inspection images using ultrasonic testing for a defective inspection object, generating three-dimensional raw data generated by stacking the collected two-dimensional inspection images, and then performing data augmentation on the raw data. As described above, the training input data is generated by dividing each two-dimensional inspection image of the raw data into a plurality of pixel patches according to the number of pooling operations of the generation network GN and performing the data augmentation. A pixel patch refers to a small section or portion of the input image that the convolutional layer processes at a given moment. More specifically, when generating input data through the data augmentation, the augmentation unit 200 divides the two-dimensional inspection images of the raw data into at least 2ⁿ pixel patches. In this case, preferably, the two-dimensional inspection images of the raw data is divided into 2ⁿ⁺¹ pixel patches. Here, n indicates the number of pooling layers or pooling operations of the generation network GN. In addition, the target data is a three-dimensional image representing a defect of the inspection object. The target data may also be generated in the same way as the input data.

Next, in step S120, the learning unit 300 inputs the input data into a generation network GN. Then, in step S130, the generation network GN generates representation data through weighting operations in which untrained or initial weights are applied to the input data. The generating of the representation data by the generation network GN in step S130 is the same as that previously described with reference to FIG. 4.

In step S140, when the representation data is generated, the learning unit 300 derives a generation loss indicating a difference between the representation data and the target data through a loss function. According to the exemplary embodiment, the learning unit 300 may calculate the generation loss according to the loss function as shown in Equation 1 below.

[Equation 1]

$${L}_{g} = 1 - {P ( o , t )}_{ijk}$$

$${P ( o , t )}_{ijk} = {\sum }_{i} {\sum }_{j} {\sum }_{k} \frac{( 2 {μ}_{o} {μ}_{t} + {C}_{1} ) ( 2 {σ}_{o} {σ}_{t} + {C}_{2} )}{( {μ}_{o}^{2} + {μ}_{t}^{2} + {C}_{1} ) ( {σ}_{o}^{2} + {σ}_{t}^{2} + {C}_{2} )}$$

where Lg indicates a generation loss. In addition, o refers to representation data and t refers to target data. In addition, P(o, t) is similarity between the representation data and the target data. Specifically, P(o, t) refers to similarity among luminance, contrast, and structures between the representation data and the target data. Indices i, j, and k (i.e., width, length, and index, respectively, see FIG. 2) are for identifying coordinates (X, Y, Z) of three-dimensional pixel patches of the representation data and target data. In addition, μ represents luminance of a corresponding pixel patch of the representation data and target data, and σ represents contrast of the corresponding pixel patch of the representation data and target data. Each of C₁ and C₂ refers to a constant value.

Next, in step S150, the learning unit 300 performs optimization for updating the weights of the generation network GN so as to maximally reduce the generation loss.

Next, in step S160, the learning unit 300 checks whether a learning completion condition is satisfied or not. Here, the learning completion condition may be a case where a generation loss is less than a preset threshold, or a case where the generation loss converges to a predefined boundary value, or a case where the number of learning counts is greater than or equal to a preset count, or a case where accuracy, a learning rate, a recall rate, intersection over union (IoU), a harmonic average (F1-score) of the accuracy and recall rate, and the like are greater than or equal to respective predetermined values. As a result of checking in step S160, in a case where the learning completion condition is not satisfied, the above-described steps S120 to S160 are repeatedly performed. Whereas, in a case where the learning completion condition is satisfied, in step S170, the learning unit 300 completes the learning of the generation network GN.

Referring to FIG. 6, when the learning of the generation network GN is completed, in step S210, the learning unit 300 prepares a plurality of second training data.

The second training data includes input data and a label corresponding to the training input data. The training input data is the same as that previously described in step S110. The label indicates a type of defect on an inspection object. Such a label may be generated through hard coding. For example, the label may be generated through a one-hot-encoding vector. For example, it is assumed that the type of defect in the inspection object to be learned includes a wrinkle and delamination. Then, detection data represents both a probability that the type of defect in the inspection object is the wrinkle and a probability that the type of defect in the inspection object is the delamination. The defect of the inspection object may be expressed for each of the wrinkle and delamination as follows: “wrinkle=[1, 0]”, and “delamination=[0, 1]”.

Next, in step S220, the learning unit 300 inputs the training input data of the plurality of second training data into a generation network GN.

Then, in step S230, the generation network GN generates representation data through weighting operations in which the fully trained weights are applied to the training input data. The generating of the representation data by the generation network GN in step S230 is the same as that previously described with reference to FIG. 4. The generated representation data is input to a detecting network DN.

Accordingly, in step S240, the detecting network DN generates detection data for predicting a type of defect as a probability through weighting operations in which untrained weights are applied to the representation data. The generating of the detection data by the detecting network DN in step S240 is the same as that previously described with reference to FIG. 4. For example, an output of the detecting network DN may be output as “[wrinkle, delamination]=[0.749, 0.251]”.

When the detection data is generated, in step S250, through a loss function, the learning unit 300 derives a prediction loss indicating a difference between the detection data and a label. According to the exemplary embodiment, the learning unit 300 may calculate the prediction loss according to the loss function as shown in Equation 2 below.

$${L}_{e} = {\sum }_{i = 1} {y}_{i} log {\hat{y}}_{i} \qquad [ Equation 2 ]$$

Here, Lₑ represents a prediction loss. In addition, y indicates a label. In addition, ŷ indicates detection data and i indicates indices of the detection data and the label.

Next, in step S260, the learning unit 300 performs optimization for updating the weights of the detecting network DN so as to maximally reduce the generation loss while the weights of the generation network GN remain unchanged in the deep learning model DLM. In other words, the weight update process, such as backpropagation, may extend all the way back to the training input data, but the weight adjustments may be made from the final output layer to the beginning of the detecting network DN.

Next, in step S270, the learning unit 300 checks whether a learning completion condition is satisfied or not. Here, the learning completion condition may be a case where a generation loss is less than a preset threshold, or a case where the generation loss converges, or a case where the number of learning counts is greater than or equal to a preset count, or a case where accuracy, a learning rate, a recall rate, an intersection over union (IoU), a harmonic average (F1-score) of the accuracy and recall rate, and the like are greater than or equal to respective predetermined values. As a result of checking in step S260, in a case where the learning completion condition is not satisfied, the above-described steps S220 to S270 are repeatedly performed. Whereas, in a case where the learning completion condition is satisfied, in step S280, the learning unit 300 completes the learning of the entire deep learning model DLM including the generation network GN and the detecting network DN.

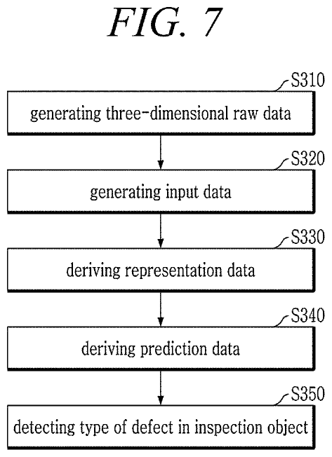

Next, a method for analyzing a defect in ultrasonic testing using the deep learning model DLM trained by the above-described method will be described. FIG. 7 is a flowchart illustrating the method for analyzing the defect in the ultrasonic testing using the three-dimensional deep learning model according to the exemplary embodiment of the present disclosure.

Referring to FIG. 7, in step S310, the collection unit 100 generates three-dimensional raw data by collecting a plurality of two-dimensional inspection images obtained by ultrasonic testing (UT) on an inspection object and stacking the plurality of collected two-dimensional images. The two-dimensional inspection images are prepared by the ultrasonic testing. That is, each inspection image is generated by scanning the inspection object by an ultrasonic testing device (UTD). The collection unit 100 may receive the two-dimensional inspection images from the ultrasonic testing device (UTD). Each of such two-dimensional inspection images generated is composed to have scan axes of B(X, Y), D(Z, Y), and C(X, Z). As shown in FIG. 2, the collection unit 100 may align and stack the two-dimensional inspection images along each axis (X, Y, Z), thereby preparing three-dimensional raw data represented in a three-dimensional form of X, Y, and Z. Here, X may be width, Y may be length, and Z may be index.

Next, in step S320, an augmentation unit 200 processes the raw data to generate input data for the deep learning model. In order to preserve features of the input data, the augmentation unit 200 performs data augmentation by dividing each two-dimensional inspection image of the raw data into a plurality of pixel patches in accordance with the number of pooling operations of the generation network GN, thereby generating the input data. More specifically, when generating the input data through the data augmentation, the augmentation unit 200 divides the two-dimensional inspection images of the raw data into at least 2ⁿ pixel patches. The augmentation unit 200 preferably divides the two-dimensional inspection images of the raw data into 2ⁿ⁺¹ pixel patches. Here, n indicates the number of pooling layers or pooling operations of the generation network GN.

Next, in step S330, the analysis unit 400 may analyze history data or data of an object of interest through the generation network GN to derive representation data. When the analysis unit 400 inputs input data to the generation network GN, the generation network GN derives the representation data by performing weighting operations in which the fully trained weights are applied to the input data. Here, the representation data is the inferenced three-dimensional image representing the defect of the inspection object. Such representation data may be represented as one or more feature maps. The method of deriving the representation data by the generation network GN is the same as that previously described with reference to FIG. 4.

Next, in step S340, the analysis unit 400 derives detection data by analyzing the representation data through the detecting network DN. In this case, the detecting network DN may derive the detection data by performing weighting operations in which full trained weights are applied to the representation data. The detection data represents a type of defect in the inspection object as a probability. For example, the learned defects are assumed to be a wrinkle and delamination. In this case, an output of the detecting network DN may be output as “[wrinkle, delamination]=[0.749, 0.251]”.

Accordingly, in step S350, the analysis unit 400 may detect the type of the defect in the inspection object according to a probability of the detection data. For example, when an output of the detecting network DN is output as “[wrinkle, delamination]=[0.749, 0.251]”, this means that there is a 75% probability that the defect in the inspection object is a wrinkle and a 25% probability that the defect in the inspection object is delamination. Accordingly, the analysis unit 400 may determine that the type of defect in the inspection object is the wrinkle. Such an analysis unit 400 may output the representation data that is the three-dimensional image representing the defect of the inspection object and the type of the detected inspection object at once.

According to the conventional technology, although one-dimensional signal data allows checking a position of a defect with coordinate values, checking a shape of the defect is difficult, and although two-dimensional image data allows checking the shape of the defect, checking a depth of the defect is difficult. However, according to the present disclosure, three-dimensional defects (i.e., three-dimension objects) which are difficult to be predicted at once may be detected by using a one-dimensional or two-dimensional model through a three-dimensional deep learning model. Three-dimensional input data is used to perform analysis, so that shapes similar to the shapes of actual defects may be analyzed. That is, in the present disclosure, the types of the three-dimensional defects (of the three-dimensional objects), which are difficult to be predicted and confirmed at once, may be predicted and confirmed at once by using one-dimensional or two-dimensional modeling. Moreover, in the present disclosure, the analysis is performed by dividing raw data into a form of pixel patches of a predetermined ratio or more, whereby a Graphics Processing Unit (GPU) may be used efficiently despite the lack of actual defect data, and small-sized defects may be recognized from large-volume image data as well. In particular, various defect types such as a wrinkle, delamination, and a dry area may be classified and analyzed in a form of three-dimensional shape.

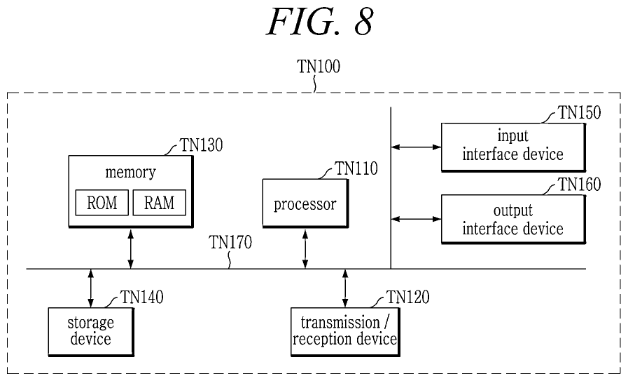

FIG. 8 is a view illustrating a computing device according to the exemplary embodiment of the present disclosure. The computing device TN100 in FIG. 8 may be a device described in the present specification (e.g., an analysis device 10, etc.).

In the exemplary embodiment of FIG. 8, the computing device TN100 may include at least one processor TN110, a transmission/reception device TN120, and a memory TN130. In addition, the computing device TN100 may further include a storage device TN140, an input interface device TN150, an output interface device TN160, etc. Components included in the computing device TN100 and connected to each other by a bus TN170 may communicate with each other.

The processor TN110 may execute a program command or instructions stored in at least one among the memory TN130 and the storage device TN140. The processor TN110 may refer to a central processing unit (CPU), a graphics processing unit (GPU), or a dedicated processor on which methods according to the exemplary embodiment of the present disclosure are performed. The processor TN110 may be configured to implement procedures, functions, methods, and the like which are described in connection with the exemplary embodiment of the present disclosure. The processor TN110 may control each component of the computing device TN100.

Each of the memory TN130 and the storage device TN140 may store various information related to the operation of the processor TN110. Each of the memory TN130 and the storage device TN140 may be comprised of at least one of a volatile storage medium and a non-volatile storage medium. For example, the memory TN130 may be comprised of at least one of read only memory (ROM) and random access memory (RAM).

The transmission/reception device TN120 may transmit or receive wired signals or wireless signals. The transmission/reception device TN120 may be connected to a network and perform communication. As mentioned, the computing device TN100 shown in FIG. 8 may be a device described in the current specification. For example, the collection unit 100 may be realized through the combination of the input interface device TN150, memory TN120, and processor TN110. This is achieved by executing instructions, stored in memory TN120, with processor TN110 to prepare three-dimensional raw data. This data is obtained by collecting, through the input interface TN150 or the transmission/reception device TN120, and stacking multiple two-dimensional inspection images from ultrasonic testing of an object under inspection. Similarly, the augmentation unit 200 may be implemented with processor TN110 and memory TN120 to process the three-dimensional raw data, thereby generating input data for a deep learning model. Furthermore, the analysis unit 300 utilizes processor TN110 and memory TN120 to transform, by executing instructions stored in memory TN120, the input data into representation data by applying first weights in a trained state. This transformation occurs within a generation network of the deep learning model. The representation data is then fed into a detection network of the model to identify the type of defect in the inspection object. Similarly, the learning unit may be implemented by executing instructions that are stored in the memory TN130, using the processor TN110.

Furthermore, the device for defect analysis may control the operation of the object being inspected based on the deep learning model's output. For instance, in the case of a turbine blade as the inspection object, the device may either reduce the turbine blade's operating speed or halt its operation entirely to facilitate repairs.

Meanwhile, various methods according to the exemplary embodiment of the present disclosure described above may be implemented in the form of programs readable through various computer means and be recorded on computer-readable recording media. Here, the recording media may store program commands, data files, data structures, etc., singly or in combination thereof. The program commands recorded on the recording media may be designed and configured specifically for the embodiment of the present disclosure or may be publicly known and available to those skilled in the art of computer software. For example, the recording media include: magnetic media such as hard disks, floppy disks, and magnetic tapes; optical media such as CD-ROMs and DVDs; magneto-optical media such as floptical disks; and a hardware device specially configured to store and execute program commands, the hardware device including such as ROM, RAM, flash memory, etc. Examples of the computer commands include not only machine language generated by a compiler, but also high-level language wires executable by a computer using an interpreter or the like. Such a hardware device described above may be configured to operate by using one or more software modules in order to perform the operation of the embodiment of the present disclosure, and vice versa.

Although the exemplary embodiment of the present disclosure has been described above, those skilled in the art will be able to modify and change the present disclosure in various ways by attaching, deleting, or adding components without departing from the spirit of the present disclosure as described in the patent claims, and this will also be included within the scope of rights of the present disclosure.

What is claimed is:

1. A method for analyzing a defect, the method comprising:
preparing three-dimensional raw data by collecting a plurality of two-dimensional inspection images obtained by ultrasonic testing of an inspection object and stacking the plurality of two-dimensional inspection images;
generating input data for a deep learning model by processing the three-dimensional raw data;
deriving representation data, which is an inferenced three-dimensional image representing the defect of the inspection object, through a first feature transformation by applying first weights in a trained state to the input data within a generation network of the deep learning model; and
determining a defect type of the inspection object by inputting the representation data to a detecting network of the deep learning model.

2. The method of claim 1, wherein the determining of the defect type comprises:
deriving detection data that predicts the defect type of the inspection object as a probability through a second feature transformation by applying second weights in the trained state to the representation data within the detecting network of the deep learning model; and
determining the defect type of the inspection object according to the probability.

3. The method of claim 1, wherein the deriving of the representation data comprises:
deriving, by a plurality of encoding modules of the generation network, a latent vector represented as a feature map by compressing the input data sequentially; and
deriving, by a latent module and a plurality of decoding modules of the generation network, the representation data by sequentially expanding the latent vector and restoring the latent vector to fit sizes of the input data.

4. The method of claim 3, wherein the deriving of the latent vector comprises:
performing, by each of one or more convolution layers of each of the plurality of encoding modules, a convolution, a batch normalization, and an activation function on the input data or on an input feature map to generate a convolved feature map; and
downsampling, by a pooling layer of each of the plurality of encoding modules, the convolved feature map through a pooling operation.

5. The method of claim 3, wherein the deriving of the representation data comprises:
performing, by each of one or more convolution layers of the latent module, a convolution, a batch normalization, and an activation function on an input feature map to generate a convolved feature map; and
upsampling, by an up-convolution layer of the latent module, the convolved feature map through an up-convolution operation.

6. The method of claim 3, wherein the deriving of the representation data comprises:
combining, by a concatenate layer of each of the plurality of decoding modules, a first feature map input from a corresponding encoding module of the plurality of encoding modules and a second feature map input from the latent module or a preceding decoding module of the plurality of decoding modules to create a combined feature map;
performing, by each of one or more convolution layers of each of the plurality of decoding modules, a convolution, a batch normalization, and an activation function on the combined feature map to generate a convolved feature map; and
upsampling, by an up-convolution layer of each of the plurality decoding modules, the convolved feature map through an up-convolution operation.

7. The method of claim 1, wherein the generating of the input data comprises dividing each of the plurality of two-dimensional inspection images into a plurality of pixel patches according to the number of pooling operations of the generation network.

8. The method of claim 1, wherein the generating of the input data comprises dividing each of the plurality of two-dimensional inspection images into 2ⁿ or more pixel patches, wherein the n is the number of pooling operations of the generation network.

9. The method of claim 1, further comprising, before the preparing of the three-dimensional raw data, training the generation network of the deep learning model by performing:
preparing a first training data comprising training input data generated through data augmentation and target data which is a three-dimensional image generated from historical three-dimensional raw data created by stacking a plurality of historical two-dimensional inspection images obtained through the ultrasonic testing of the inspection object with the defect;
inputting the training input data into the generation network;
generating the representation data through the first feature transformation by applying the first weights in an untrained state to the training input data;
deriving a generation loss representing a difference between the representation data and the target data through a first loss function; and
updating the first weights of the generation network based on the generation loss so as to maximally reduce the generation loss.

10. The method of claim 9, wherein, in the deriving of the generation loss, the generation loss is generated according to Equations below:
$${L}_{g} = 1 - {P ( o , t )}_{ijk}$$
$${P ( o , t )}_{ijk} = {\sum }_{i} {\sum }_{j} {\sum }_{k} \frac{( 2 {μ}_{o} {μ}_{t} + {C}_{1} ) ( 2 {σ}_{o} {σ}_{t} + {C}_{2} )}{( {μ}_{o}^{2} + {μ}_{t}^{2} + {C}_{1} ) ( {σ}_{o}^{2} + {σ}_{t}^{2} + {C}_{2} )}$$
where the L_{g} is the generation loss,
the o is the representation data,
the t is the target data,
the P(o, t) is a similarity between the representation data and the target data,
the i, the j, and the k are indices for identifying coordinates of a three-dimensional pixel patch of each of the representation data and target data,
each of the who and the μₜ is a luminance of the three-dimensional pixel patch of the representation data and target data, respectively,
each of the σₒ and the σₜ is a contrast of the three-dimensional pixel patch of the representation data and target data, respectively, and
each of the C₁ and the C₂ represents a constant.

11. The method of claim 9, further comprising training the detecting network of the deep learning model by performing:
preparing second training data comprising the training input data and a label indicating the defect type of the inspection object;
inputting the training input data into the generation network;
generating, by the generation network, the representation data through the first feature transformation by applying the first weights in the trained state to the training input data;
inputting the representation data into the detecting network;
generating, by the detecting network, detection data that predicts the defect type as a probability through a second feature transformation by applying second weights in the untrained state to the representation data;
deriving, by the detecting network, a prediction loss representing a difference between the detection data and the label through a second loss function; and
updating, by the detecting network, the second weights of the generation network based on the prediction loss so as to maximally reduce the prediction loss while the first weights of the detecting network remain unchanged during the updating of the second weights in the deep learning model.

12. A device for analyzing a defect, the device comprising a processor; a memory coupled to the processor; and instructions stored in the memory, which, when executed by the processor, cause the device to:
prepare three-dimensional raw data by collecting a plurality of two-dimensional inspection images obtained by ultrasonic testing of an inspection object and stacking the plurality of two-dimensional inspection images;
generate input data for a deep learning model by processing the three-dimensional raw data;
derive representation data, which is an inferenced three-dimensional image representing the defect of the inspection object, through a first feature transformation by applying first weights in a trained state to the input data within a generation network of the deep learning model; and
determine a defect type of the inspection object by inputting the representation data to a detecting network of the deep learning model.

13. The device of claim 12, wherein the defect type is determined by:
deriving detection data that predicts a defect type of the inspection object as a probability through a second feature transformation by applying second weights in the trained state to the representation data within the detecting network of the deep learning model, and
determining the defect type of the inspection object according to the probability.

14. The device of claim 13, wherein the generation network comprises:
a plurality of encoding modules configured to derive a latent vector represented as a feature map by compressing the input data sequentially; and
a latent module and a plurality of decoding modules, which are configured to derive representation data by sequentially expanding the latent vector and restoring the latent vector to fit sizes of the input data.

15. The device of claim 14, wherein each of the plurality of encoding modules comprises:
each of one or more convolution layers configured to perform a convolution, a batch normalization, and an activation function on the input data or an input feature map to generate a convolved feature map; and
a pooling layer configured to downsample the convolved feature map through a pooling operation,
the latent module comprises:
each of the one or more convolution layers configured to perform the convolution, the batch normalization, and the activation function on the input feature map to generate the convolved feature map; and
an up-convolution layer configured to upsample the convolved feature map through an up-convolution operation, and
each of the plurality of decoding modules comprises:
a concatenate layer configured to combine a first input feature map input from a corresponding encoding module and a second input feature map input from the latent module or a previous decoding module to generate a combined feature map;
each of the one or more convolution layers configured to perform the convolution, the batch normalization, and the activation function on the input feature map to generate the convolved feature map; and
an up-convolution layer configured to upsample the convolved feature map through an up-convolution operation.

16. The device of claim 12, wherein the input data is generated through data augmentation, which comprises dividing each of the plurality of two-dimensional inspection images into a plurality of pixel patches according to the number of pooling operations of the generation network.

17. The device of claim 12, wherein the input data is generated through data augmentation, which comprises dividing each of the plurality of two-dimensional inspection image into 2ⁿ or more pixel patches wherein the n is the number of pooling operations of the generation network.

18. The device of claim 12, wherein, before the three-dimensional raw data is prepared, the device is further configured to train the generation network of the deep learning model by performing:
preparing first training data comprising training input data generated through data augmentation and target data which is a three-dimensional image generated from historical three-dimensional raw data created by stacking a plurality of historical two-dimensional inspection images obtained through the ultrasonic testing of the inspection object with the defect,
inputting the training input data into the generation network,
generating the representation data through the first feature transformation by applying the first weights in an untrained state to the training input data,
deriving a generation loss representing a difference between the representation data and the target data through a first loss function, and
updating the first weights of the generation network based on the generation loss so as to maximally reduce the generation loss.

19. The device of claim 18, wherein the generation loss is generated according to Equations below:
$${L}_{g} = 1 - {P ( o , t )}_{ijk}$$
$${P ( o , t )}_{ijk} = {\sum }_{i} {\sum }_{j} {\sum }_{k} \frac{( 2 {μ}_{o} {μ}_{t} + {C}_{1} ) ( 2 {σ}_{o} {σ}_{t} + {C}_{2} )}{( {μ}_{o}^{2} + {μ}_{t}^{2} + {C}_{1} ) ( {σ}_{o}^{2} + {σ}_{t}^{2} + {C}_{2} )}$$
where the L_{g} is the generation loss,
the o is the representation data,
the t is the target data,
the P(o, t) is a similarity between the representation data and the target data,
the i, the j, and the k are indices for identifying coordinates of a three-dimensional pixel patch of each of the representation data and target data,
each of the μₒ and the μₜ is a luminance of the three-dimensional pixel patch of the representation data and target data, respectively,
each of the σₒ and the σₜ is contrast of the three-dimensional pixel patch of the representation data and target data, respectively, and
each of the C₁ and the C₂ represents a constant.

20. The device of claim 19, wherein the device is further configured to train the detecting network of the deep learning model by performing:
preparing second training data comprising the training input data and a label indicating the defect type of the inspection object,
inputting the training input data into the generation network,
generating, by the generation network, the representation data through the first feature transformation by applying the first weights in the trained state to the training input data,
inputting the representation data into the detecting network,
generating, by the detecting network, detection data that predicts the defect type as a probability through a second feature transformation by applying second weights in the untrained state to the representation data,
deriving, by the detecting network, a prediction loss representing a difference between the detection data and the label through a second loss function, and
updating, by the detecting network, the second weights of the generation network based on the prediction loss so as to maximally reduce the prediction loss while the first weights of the detecting network remain unchanged during the updating of the second weights in the deep learning model.
